(19) United States
(12) Patent Application Publication
(10) Pub. No.: US 2008/0268579 A1
(43) Pub. Date: Oct. 30, 2008

(54) SEMICONDUCTOR CHIP PACKAGE AND METHOD OF FABRICATING THE SAME

(75) Inventors: Hae-Jung YU, Gyeonggi-do (KR); Mu-Seob SHIN, Chungcheongnam-do (KR); Tae-Joo HWANG, Gyeonggi-do (KR); Tae-Gyeong CHUNG, Gyeonggi-do (KR); Eun-Chul AHN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/110,215

(22) Filed: Apr. 25, 2008

(30) Foreign Application Priority Data
Apr. 25, 2007 (KR) 2007-0040484

(51) Int. Cl. H01L 21/56

(52) U.S. Cl. 438/127; 257/E21.502

(57) ABSTRACT

A semiconductor chip package capable of improving reliability at a chip interconnection portion and improving reliability in a solder joint by reducing thermal and mechanical stresses at an external portion of the package including a solder ball land, and a method of fabricating the package are provided. The method of fabricating a semiconductor chip package includes providing a substrate; forming a first underfill on a first portion of the substrate; forming a second underfill at a chip interconnection portion of the substrate; and mounting a semiconductor chip on the chip interconnection portion using conductive bumps. In the method, the second underfill is formed of a material having a modulus higher than the first underfill.

### CROSS-REFERENCE TO RELATED PATENT APPLICATION

This application claims priority under 35 USC § 119 to Korean Patent Application No. 10-2007-0040484, filed on Apr. 25, 2007 in the Korean Intellectual Property Office, the disclosure of which is incorporated herein in its entirety by reference.

### BACKGROUND

1. Technical Field

The present invention relates to a semiconductor device and a method of fabricating the same, and more particularly, to a semiconductor chip package and a method of fabricating the same.

2. Description of the Related Art

As demands for high-performance and high-speed semiconductor devices increase, requirements on flip chip packages to meet such demands are also increasing. However, it is very difficult to develop an underfill material capable of ensuring reliability at a die or chip interconnection portion of a flip chip package and reliability after a chip is mounted on a module substrate, e.g., a printed circuit board (PCB).

Conventionally, a flip chip package includes a PCB substrate, a flip chip mounted on the substrate, an underfill for filling between the substrate and the chip, and a sealant such as an epoxy molding compound (EMC) for sealing the chip. Also, solder balls for mounting the flip chip package on an external substrate, such as a main board, are formed beneath a bottom surface of the substrate.

The conventional flip chip package as described above is formed using a single type of underfill. A high modulus underfill is typically used to improve the aforementioned reliability at a chip interconnection portion and reliability after chip mounting. However, when the high modulus underfill is used, thermal and mechanical stresses are concentrated on a solder ball land, i.e., a portion at which the solder balls are formed beneath the bottom surface of the PCB substrate, due to physical expansion and contraction depending on a change in temperature. For this reason, solder joint cracks occur. Therefore, there is a problem in that the reliability of the conventional flip chip package using an underfill made of a single material is degraded at a board level.

### SUMMARY

The present invention provides a semiconductor chip package capable of improving reliability at a chip interconnection portion and improving reliability in a solder joint by reducing thermal and mechanical stresses at an external portion of the package including a solder ball land, and a method of fabricating the package.

According to an aspect of the present invention, there is provided a semiconductor chip package, which includes a substrate; a semiconductor chip mounted on the substrate; a first underfill formed at a chip interconnection portion of the substrate; and a second underfill formed at a portion other than the chip interconnection portion on the substrate, wherein the first underfill is formed of a material having a modulus higher than the second underfill.

In a semiconductor chip package and a method of fabricating the same according to the present invention, a high modulus underfill is formed at a chip interconnection portion and a low modulus underfill is formed at a portion other than the chip interconnection portion. In this way, reliability at the chip interconnection portion can be maintained and stresses concentrated on a solder ball land can be reduced. Accordingly, both reliability at the chip interconnection portion and reliability in a solder joint can be improved.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a flip chip package according to an embodiment of the present invention;

FIG. 2 is a plan view showing a structure of an underfill formed on a substrate of the flip chip package of FIG. 1;

FIGS. 3A through 3D are cross-sectional views illustrating a method of fabricating a flip chip package according to an embodiment of the present invention; and

FIGS. 4A and 4B are cross-sectional views illustrating a method of fabricating a flip chip package according to another embodiment of the present invention.

### DETAILED DESCRIPTION

The present invention will now be described more fully hereinafter with reference to the accompanying drawings, in which preferred embodiments of the invention are shown. In the drawings, it will be understood that when an element such as a layer, film, region or substrate is referred to as being “on” another element, it can be directly on the other element or intervening elements may also be present. In contrast, when an element is referred to as being “directly on” another element, there are no intervening elements present. The thickness of layers, films and regions are exaggerated for clarity. Like numerals refer to like elements throughout the specification. Meanwhile, the terminology used herein is for the purpose of describing particular embodiments only and is not intended to be limiting of the invention.

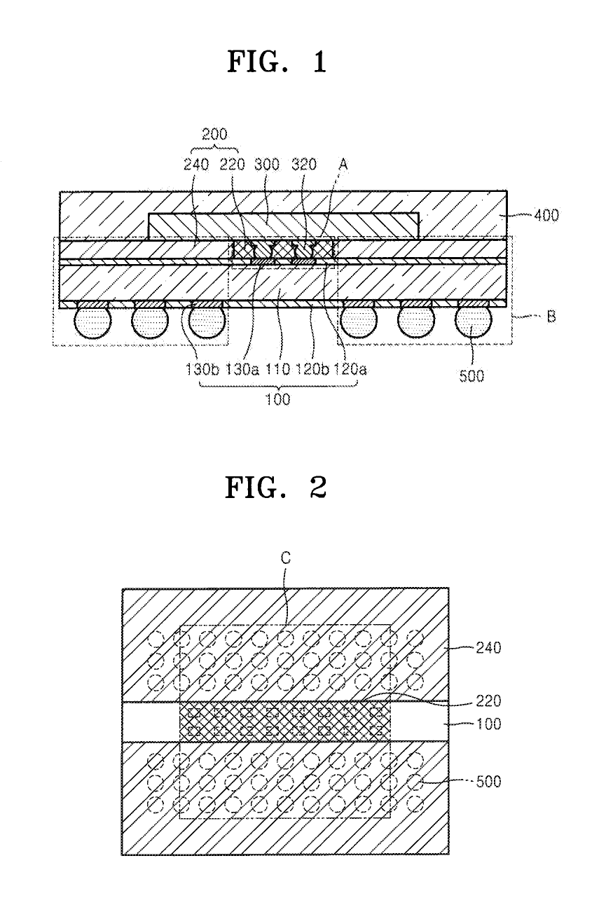

FIG. 1 is a cross-sectional view of a flip chip package according to an embodiment of the present invention.

Referring to FIG. 1, the flip chip package of this embodiment includes a substrate 100, a flip chip 300 mounted on the substrate 100, an underfill 200 formed between the substrate 100 and the chip 300, a sealant or an encapsulant 400 for sealing the chip 300, and external connection terminals, for example solder balls, 500 formed beneath a bottom surface of the substrate 100.

In the flip chip package of this embodiment, the underfill 200 is formed using an underfill material made of different materials by dividing the underfill 200 into a chip interconnection portion A and a portion B other than the chip interconnection portion A, unlike the conventional flip chip package. Specifically, an interconnection portion underfill 220 made of a high modulus material is filled in the chip interconnection portion A, and an edge underfill 240 made of a low modulus material is filled in the portion B.

In general, the portion B includes a solder ball land upon which the solder balls 500 are formed beneath the bottom surface of the substrate 100. The substrate 100 may be, for example, a PCB substrate. Such a PCB substrate may include a core 110, photo solder resists (PSRs) 120a and 120b respectively formed on and beneath the core 110, and upper and lower pads 130a and 130b to which conductive bumps 320 of the chip 300 and the solder balls 500 are respectively adhered.

Preferably, the modulus of the interconnection portion underfill 220 is approximately four times higher than that of the edge underfill 240. When the interconnection portion underfill 220 is formed of a material having a modulus of a few GPa and the edge underfill 240 is formed of a material having a modulus of a few tens to a few hundreds of GPa in an experiment, it can be shown that stresses applied to the solder ball land are greatly reduced. That is, a low modulus underfill is used at an external portion including the solder ball land in the flip chip package of the present invention, so that stresses concentrated on the solder ball land can be reduced. Accordingly, defects at a board level, such as defects in a solder joint of a flip chip package, can be decreased.

For example, according to experimental data, during a temperature cycle of −25 to +125° C., defects of the package at a board level are decreased four times more than those of the conventional package. That is, in the present invention, a high modulus underfill is used at a chip interconnection portion A and a low modulus underfill is used at a portion other than the chip interconnection portion, i.e., the region indicated as B, so that reliability in a solder joint of the flip chip package can be increased four times or more.

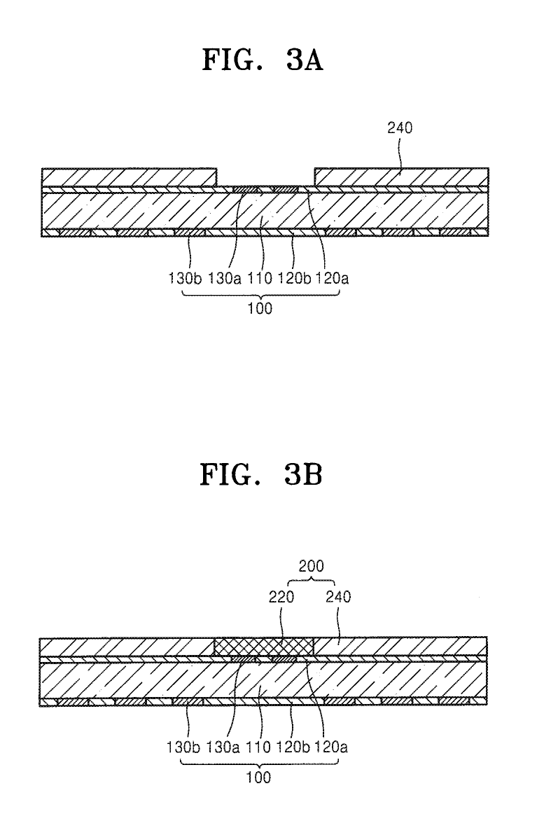

FIG. 2 is a plan view showing a structure of an underfill formed on a substrate of the flip chip package of FIG. 1. In FIG. 2, a chip and a sealant are not shown on the underfill.

Referring to FIG. 2, the underfill 200 is illustrated on the substrate 100. It can be seen that the interconnection portion underfill 220 is formed where the flip chip 300 is mounted, i.e., a chip interconnection portion A. Preferably, the interconnection portion underfill 220 is formed at an approximately central portion of a portion where the flip chip 300 is mounted. The edge underfill 240 is formed at an external portion other than the chip interconnection portion A. It will be apparent that the modulus of the interconnection portion underfill 220 is higher than that of the edge underfill 240 as described above. Circles shown in a dotted line represent the solder balls 500 formed on the bottom surface of the substrate 100. Detail C represents an approximate area where the chip is disposed.

As shown in FIG. 2, an underfill is not formed at a predetermined portion extending from the chip interconnection portion on the substrate 100 on which the chip 300 is not disposed. This is for the purpose of more easily forming the interconnection portion and edge underfills 220 and 240. However, according to some embodiments, the underfill 200 may be formed at a portion on which the chip 300 is not disposed, as desired.

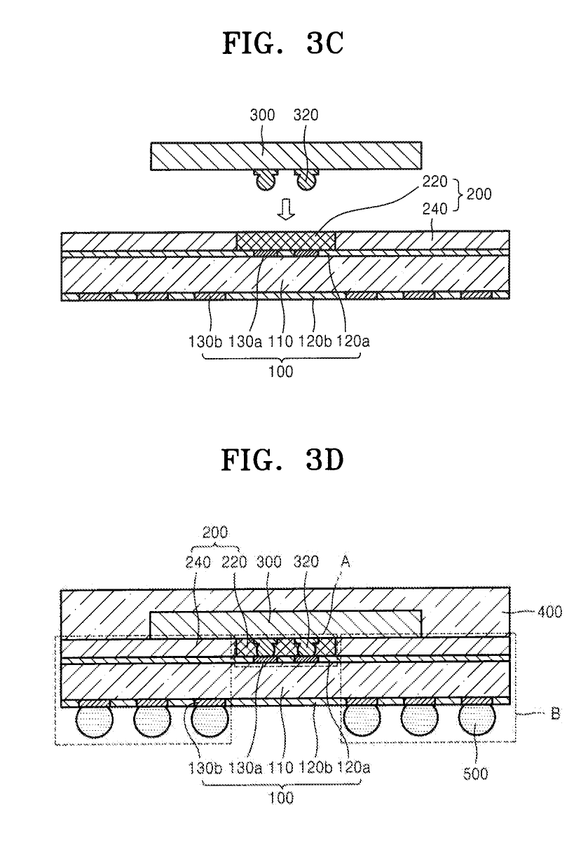

FIGS. 3A through 3D are cross-sectional views illustrating a method of fabricating a flip chip package according to an embodiment of the present invention.

Referring to FIG. 3A, an edge underfill 240 is first formed on a substrate 100. The edge underfill 240 may be formed through a printing method at an external portion on the substrate 100 excluding a chip interconnection portion and a predetermined portion extended therefrom. The substrate 100 may be a PCB substrate as described above. Such a PCB substrate may include a core 100, PSRs 120a and 120b respectively formed on and beneath the core 110, and upper and lower pads 130a and 130b to which bumps 320 of a chip and solder balls 500 are respectively adhered.

Referring to FIG. 3B, after forming the edge underfill 240, an interconnection portion underfill 220 is formed at the chip interconnection portion. The interconnection portion underfill 220 may be formed through a writing or dotting method, for example. However, other suitable methods can be used within the spirit and scope of the present invention. The interconnection portion underfill 220 may be formed so as to be precisely filled in the chip interconnection portion in which the bumps 320 of the chip will be connected to the upper pads 130a on the substrate 100.

Referring to FIG. 3C, after forming the interconnection portion underfill 220, a flip chip 300 is mounted on the underfill 200 such that the bumps 320 formed beneath the chip 300 can be accurately joined to the upper pads 130a on the substrate 100. Such mounting of the chip 300 may be performed by known techniques such as thermally pressing and joining the chip 300 to the upper pads 130 using the bumps 320, e.g., gold studs, solder bumps, Cu pillars, or the like. After mounting the chip 300, a curing heat treatment is performed, in which heat treatments for different underfills, i.e., the interconnection portion and edge underfills 220 and 240, can be performed at the same time or in successive steps.

Accordingly, in the method of fabricating a flip chip package according to some embodiments of the present invention, an interconnection portion underfill is formed on a substrate, and then a flip chip is mounted thereon. In this way, a problem of fillet control or underfill gaps occurring in conventional methods can be easily avoided.

Referring to FIG. 3D, after mounting the chip 300, a sealant or an encapsulant 400 such as an epoxy molding compound (EMC) is coated on substantially the entire surface of the substrate 100 to seal the chip 300. The solder balls 500 may be formed on the lower pads 130b of the substrate 100.

In the method of fabricating a flip chip package according to the present invention, a high modulus underfill is used at a chip interconnection portion A, and a low modulus underfill is used at a portion other than the chip interconnection portion A, i.e., an external portion B of the substrate 100 including a solder ball land. Accordingly, a problem of defects in a solder joint at a board level, which occurs due to the use of the conventional underfill made of a single material, can be avoided.

In the flip chip package of the present invention, a high modulus underfill is used at a chip interconnection portion, so that reliability at the chip interconnection portion can be maintained, and a low modulus underfill is used at an external portion of a substrate including a solder ball land, so that stresses concentrated on the solder ball land can be reduced.

Accordingly, in the flip chip package fabricated according to the present invention, the occurrence of defects at a board level, such as defects of a solder joint, can be decreased.

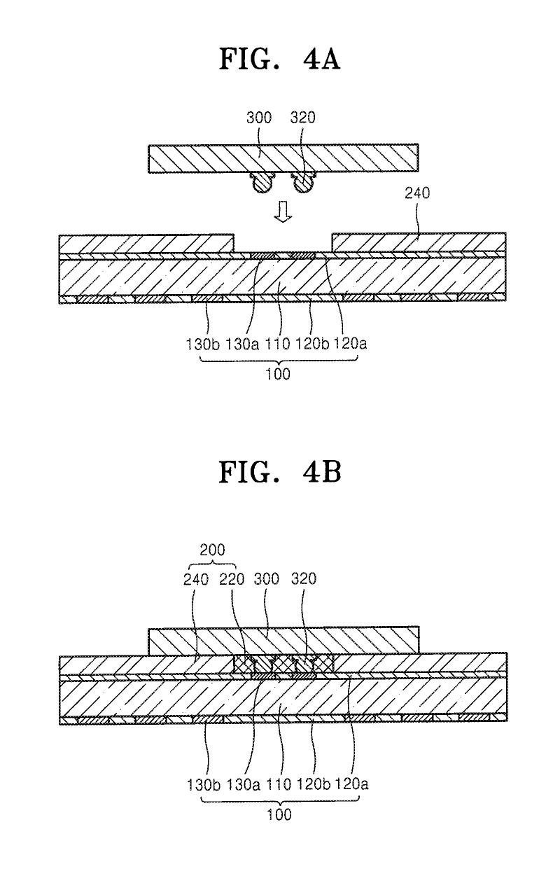

FIGS. 4A and 4B are cross-sectional views illustrating a method of fabricating a flip chip package according to another embodiment of the present invention. In this embodiment, descriptions overlapping with the aforementioned embodiment will be omitted.

Referring to FIG. 4A, in this embodiment, after forming an edge underfill 240, an interconnection portion underfill 220 is not immediately formed. Instead, a flip chip 300 is first mounted on a substrate 100, unlike in FIG. 3B. Bumps 320 beneath the chip 300 are joined to upper pads 130a on the substrate 100 through a thermal pressing method, so that the chip 300 can be mounted on the substrate 100.

Referring to FIG. 4B, after mounting the chip 300 on the substrate 100, the interconnection portion underfill 220 is filled between the chip 300 and the substrate 100 at a chip interconnection portion. Subsequent processes of forming a sealant 400 and solder balls 500 are performed similar to the aforementioned embodiment.

In this embodiment, an interconnection portion underfill is formed after mounting a flip chip on a substrate. However, a high modulus underfill is used at a chip interconnection portion, and a low modulus underfill is used at an external portion of the substrate including a solder ball land, so that reliability at the chip interconnection portion can be maintained and reliability at a board level can be enhanced.

As described above, in a flip chip package and a method of fabricating the same according to the present invention, a high modulus underfill is formed at a chip interconnection portion in which a flip chip is connected to a substrate, and a low modulus underfill is formed at a portion other than the chip interconnection portion, so that reliability at the chip interconnection portion can be maintained and stresses concentrated on a solder ball land can be reduced. Accordingly, both reliability at the chip interconnection portion and reliability of a solder joint are enhanced, so that reliability at a board level can be improved.

In the method of fabricating a flip chip package according to the present invention, an interconnection portion underfill is first formed, and a flip chip is then mounted thereon. For this reason, a problem of fillet control and/or underfill gaps occurring in conventional methods can be avoided. Further, the present invention provides an advantage in that a curing heat treatment for the different underfills can be performed at the same time.

According to an aspect of the present invention, there is provided a flip chip package, which includes a substrate; a flip chip mounted on the substrate; a first underfill formed at a chip interconnection portion that is a portion in which the chip is electrically connected to the substrate; and a second underfill formed at a portion other than the chip interconnection portion on the substrate, wherein the first underfill is formed of a material having a modulus higher than the second underfill.

In the present invention, the first underfill may have a modulus four times higher than the second underfill. Meanwhile, the chip interconnection portion may be formed at an approximately central portion on the substrate, and the chip may be electrically connected to the substrate through conductive bumps. An underfill may not be formed at a predetermined portion extended from the chip interconnection portion on the substrate on which the chip is not disposed.

In the present invention, the conductive bumps may be gold stud bumps, and the portion other than the chip interconnection portion may include a solder ball land upon which solder balls are formed beneath the substrate. Meanwhile, the substrate may be a printed circuit board (PCB).

According to another aspect of the present invention, there is provided a method of fabricating a flip chip package, which includes providing a substrate; forming a first underfill on a first portion of the substrate; forming a second underfill on a second portion of the substrate, the second portion including a chip interconnection portion in which the substrate and a flip chip are electrically connected to each other; and mounting the flip chip on the chip interconnection portion using conductive bumps, wherein the second underfill comprises a material having a modulus higher than the first underfill.

In the present invention, forming the second underfill may include a writing or dotting method, and forming the first underfill may include a printing method. As described above, the second underfill may have a modulus approximately four times higher than the first underfill.

After the operation of mounting the flip chip, the method of fabricating a flip chip package may further include performing a curing heat treatment on the first and second underfills; sealing the flip chip with a sealant; and forming a plurality of external connection terminals beneath the substrate.

According to another aspect of the present invention, there is provided a method of fabricating a flip chip package, which includes providing a substrate; forming a first underfill on a first portion of the substrate; mounting a flip chip on a chip interconnection portion using conductive bumps, the chip interconnection portion including a portion of the substrate in which the flip chip and the substrate are electrically connected to each other; and forming a second underfill on a second portion of the substrate, the second portion of the substrate including the chip interconnection portion, wherein the second underfill comprises a material having a modulus higher than the first underfill.

In a flip chip package and a method of fabricating the same according to the present invention, a high modulus underfill is formed at a chip interconnection portion, and a low modulus underfill is formed at a portion other than the chip interconnection portion, so that reliability at the chip interconnection portion can be maintained and stresses concentrated on a solder ball land can be reduced. Accordingly, both reliability at the chip interconnection portion and reliability in a solder joint can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a flip chip package, comprising:
providing a substrate;
forming a first underfill on a first portion of the substrate;
forming a second underfill on a second portion of the substrate, the second portion including a chip interconnection portion; and
mounting a semiconductor chip on the chip interconnection portion of the substrate such that the substrate and the semiconductor chip are electrically connected to each other in the chip interconnection portion,
wherein the second underfill comprises a material having a modulus higher than the first underfill.

2. The method of claim 1, wherein forming the second underfill comprises a writing or dotting method and wherein forming the first underfill comprises a printing method.

3. The method of claim 1, wherein the second underfill has a modulus approximately four times higher than the first underfill.

4. The method of claim 1, wherein the chip interconnection portion is disposed at an approximately central portion on the substrate, the first and second underfills are not disposed at a predetermined portion extending from the chip interconnection portion, and the predetermined portion includes a portion on which the semiconductor chip is not disposed.

5. The method of claim 1, further comprising, after mounting the semiconductor chip:
performing a curing heat treatment on the first and second underfills;
sealing the semiconductor chip; and
forming a plurality of external connection terminals beneath the substrate.

6. The method of claim 5, wherein the first portion includes a plurality of external connection terminal lands upon which the external connection terminals are formed.

7. The method of claim 1, wherein the substrate is a printed circuit board (PCB).

8. The method of claim 1, wherein mounting the semiconductor chip comprises using conductive bumps.

9. The method of claim 8, wherein the conductive bumps comprise at least one of gold studs, solder bumps, and Cu pillar bumps.

10. The method of claim 1, wherein the semiconductor chip is a flip chip.

11. A method of fabricating a semiconductor chip package, comprising:
providing a substrate;
forming a first underfill on a first portion of the substrate;
mounting a semiconductor chip on a chip interconnection portion of the substrate; and
forming a second underfill on the chip interconnection portion, the chip interconnection portion including a portion of the substrate in which the semiconductor chip and the substrate are electrically connected to each other,
wherein the second underfill comprises a material having a modulus higher than the first underfill.

12. The method of claim 11, wherein the second underfill has a modulus approximately four times higher than the first underfill.

13. The method of claim 11, wherein the chip interconnection portion includes an approximately central portion on the substrate, the first and second underfills are not formed at a predetermined portion extending from the chip interconnection portion, and the predetermined portion includes a portion on which the semiconductor chip is not disposed.

14. The method of claim 11, further comprising, after forming the second underfill:
performing a curing heat treatment on the first and second underfills;
sealing the semiconductor chip; and
forming external connection terminals beneath the substrate.

15. The method of claim 14, wherein the first portion includes a plurality of external connection terminal lands upon which the external connection terminals are formed.

16. The method of claim 11, wherein forming the second underfill comprises a writing or dotting method and wherein forming the first underfill comprises a printing method.

17. The method of claim 11, wherein mounting the semiconductor chip comprises using conductive bumps.

18. The method of claim 11, wherein the semiconductor chip is a flip chip.

19. A method of fabricating a flip chip package, comprising:
providing a substrate;
forming a first underfill on a first portion of the substrate;
forming a second underfill on a second portion of the substrate, the second portion including a chip interconnection portion; and
mounting a semiconductor chip on the chip interconnection portion of the substrate such that the substrate and the semiconductor chip are electrically connected to each other in the chip interconnection portion,
wherein the second underfill comprises a material having a modulus different than that of the first underfill.

20. The method of claim 19, wherein the second underfill comprises a material having a modulus higher than that of the first underfill.
